(19) United States
(12) Patent Application Publication
(10) Pub. No.: US 2013/0150502 A1
(43) Pub. Date: Jun. 13, 2013

(54) STABILIZED PHOTOACTIVE COMPOSITION AND USE THEREOF

(71) Applicant: Eni S.P.A., Roma (IT)

(72) Inventors: Alessandra Cominetti, Novara (IT); Mario Salvalaggio, Moriondo Torinese (IT); Vincenzo Malatesta, S. Maurizio (IT)

(73) Assignee: Eni S.P.A., Roma (IT)

(21) Appl. No.: 13/759,545

(22) Filed: Feb. 5, 2013

Related U.S. Application Data
(63) Continuation of application No. PCT/EP2011/063471, filed on Aug. 4, 2011.

(30) Foreign Application Priority Data
Aug. 6, 2010 (IT) MI2010A001513

(51) Int. Cl. H01L 51/00

(52) U.S. Cl. CPC H01L 51/0038; H01L 51/0035
USPC 524/91; 524/100; 524/87; 524/236; 524/99; 524/195; 524/93; 524/110

(57) ABSTRACT

Stabilized photoactive composition comprising at least one photoactive organic polymer; at least one light stabilizer selected from hindered amines; at least one UV absorber selected from triazines, benzoxazinones, benzotriazoles, benzophenones, benzoates, formamidines, cinnamates or propenoates, aromatic propanediones, benzoimidazoles, cycloaliphatic ketones, formanilides including oxamides, cyanoacrylates, benzopyranones, salicylates, or mixtures thereof. Said photoactive composition can be advantageously used in the construction of photovoltaic devices such as, for example, photovoltaic cells, photovoltaic modules, solar cells, solar modules, on both rigid and flexible supports.

### RELATED APPLICATION

This application is a Continuation of PCT/EP2011/063471, filed Aug. 4, 2011, which claims priority from Italian Application No. MI2010A001513, filed Aug. 6, 2010, the subject matter of which are incorporated herein by reference in their entirety.

### FIELD OF INVENTION

The present invention relates to a stabilized photoactive composition.

More specifically, the present invention relates to a stabilized photoactive composition comprising at least one photoactive organic polymer, at least one light stabilizer and at least one UV stabilizer.

The present invention also relates to the use of said composition in the construction of photovoltaic devices such as, for example, photovoltaic cells, photovoltaic modules, solar cells, solar modules, on both rigid and flexible supports.

### BACKGROUND

Photovoltaic devices are capable of converting the energy of a luminous radiation into electric energy. At present, most of the photovoltaic devices which can be used for practical applications exploit the physico-chemical properties of photoactive materials of the inorganic type, in particular high-purity crystalline silicon. As a result of the high production costs of silicon, scientific research has been orienting its efforts towards the development of alternative organic materials having a polymeric structure (so-called “polymer photovoltaic cells”). Unlike high-purity crystalline silicon, in fact, organic polymers are characterized by a quite easy synthesis, and control of the optoelectronic properties, a low production cost, a reduced weight of the relative photovoltaic device, in addition to allowing the recycling of said polymer at the end of the life-cycle of the device in which it is used.

The functioning of polymer photovoltaic cells is based on the combined use of an electron acceptor compound and an electron donor compound. In the state of the art, the most widely-used donor and acceptor compounds in photovoltaic devices are π-conjugated polymers belonging to the groups of poly(paraphenylene vinylenes) and of polythiophenes. The former can be used as both acceptor compounds and as donor compounds, on the basis of the electronic properties determined by the substituent groups of the polymeric chain. Polythiophenes are normally used as donor compounds. Derivatives of fullerene are most widely-used as acceptor compounds.

It is known that photovoltaic devices, in particular photovoltaic cells, solar cells, photovoltaic modules or solar modules, are generally assembled outside, on roof-tops or in wide-open spaces, in order to allow their maximum exposure to solar light.

It is also known that, as the presence of light, oxygen and/or humidity negatively influences the performances of said photovoltaic devices, these photovoltaic devices are generally encapsulated in order to increase their useful life.

American patent application US 2007/0295390, for example, describes a device comprising a solar cell individually encapsulated, wherein the solar cell comprises at least one protective layer coupled with at least one surface of the solar cell, the protective layer having a chemical composition capable of substantially preventing the contact between the solar cell and humidity; wherein the light passes through the protective layer so as to reach the absorbing layer of the solar cell; wherein the protective layer substantially comprises inorganic material. The above-mentioned protective layer is said to be capable of improving protection with respect to the outer environment of solar cells, in particular thin-film solar cells.

International patent application WO 2006/093936 describes a composition which can be used for encapsulating photovoltaic cells, including: (a) a polymeric encapsulating agent [e.g. an ionomer, an ethylene-vinyl acetate copolymer (EVA), or a block copolymer (Kraton G1726)]; (b) Cyasorb UV-1164 as UV absorber; and (c) a hindered amine as light stabilizer; wherein said UV absorber is present in the composition in a quantity ranging from about 0.2% by weight to about 1.0% by weight and the light stabilizer is present in a quantity ranging from about 0.3% by weight to about 0.6% by weight. The above composition is said to have an enhanced photothermal and photochemical stability.

The encapsulation of these photovoltaic devices, however, requires a prolonged production time and increase in the production costs which, particularly in the case of polymer photovoltaic devices generally having a low conversion efficiency of solar radiation (between about 3% and about 7%) makes their production cost even more unfavourable. Furthermore, particularly in the case of photovoltaic devices on flexible supports, this encapsulation requires the use of specific polymers having particular barrier property with respect to oxygen and/or water vapour (e.g., polymers having a very low permeability).

### BRIEF DESCRIPTION OF THE DRAWINGS

FIG. 1 illustrates the evolution of the IR spectra (carbonyl area) of the poly(3-hexylthiophene) (P3HT) film, obtained from solution A (film thickness 0.6 μm) following Suntest irradiation for the hours indicated.

FIG. 2 illustrates the evolution of the UV-Vis spectra of the poly(3-hexylthiophene) (P3HT) film, obtained from solution A (film thickness 0.6 μm) following Suntest irradiation for the hours indicated.

FIG. 3 illustrates P3HT: poly(3-hexylthiophene) film obtained from solution A (film thickness 0.6 μm); C: film obtained from solution C (film thickness 0.6 μm).

FIG. 4 illustrates the evolution of the UV-Vis spectra of the film obtained from solution E1 (film thickness 80 nm) following Suntest irradiation for the hours indicated.

FIG. 5 illustrates the P3HT: poly(3-hexylthiophene) film obtained from solution A1 (film thickness 80 nm); D1: film obtained from solution D1 (film thickness 80 nm); E1: film obtained from solution E1 (film thickness 80 nm).

### DETAILED DESCRIPTION

The Applicant has therefore faced the problem of obtaining photovoltaic devices stable to the action of light, oxygen, humidity, avoiding the above-mentioned encapsulation. The Applicant, in particular, has faced the problem of avoiding encapsulation with the use of specific polymers having particular barrier properties with respect to oxygen and/or water vapour.

The Applicant has now found that the addition of at least one light stabilizer and of at least one UV absorber to photoactive organic polymers which can be used in the construction of photovoltaic devices, is capable of stabilizing said polymers. The use of the polymers thus stabilized avoids encapsulation of the photovoltaic devices constructed therewith. In particular, the use of the polymers thus stabilized avoids encapsulation of the photovoltaic devices constructed therewith, consequently avoiding the use of specific polymers having particular barrier properties with respect to oxygen and/or water vapour.

An object of the present invention therefore relates to a stabilized photoactive composition comprising: at least one photoactive organic polymer; at least one light stabilizer selected from hindered amines; at least one UV absorber selected from triazines, benzoxazinones, benzotriazoles, benzophenones, benzoates, formamidines, cinnamates or propenoates, aromatic propandiones, benzoimidazoles, cycloaliphatic ketones, formanilides including oxamides, cyanoacrylates, benzopyranones, salicylates, or mixtures thereof.

According to a preferred embodiment of the present invention, said photoactive organic polymer can be selected from:
(a) polythiophenes such as poly(3-hexylthiophene) (P3HT), poly(3-octylthiophene), poly(3,4-ethylenedioxythiophene), or mixtures thereof;
(b) polyphenylenevinylenes such as poly(2-methoxy-5-(2-ethylexyloxy)-1,4-phenylenevinylene, poly(para-phenylenevinylene), {(poly[2-methoxy-5-(3,7-dimethyl-octyloxy)-1,4-phenylene]-alt-vinylene)}(MDMO-PPV), or mixtures thereof;
(c) alternating conjugated copolymers comprising:
naphthalenediimide units (A) having general formula (I):

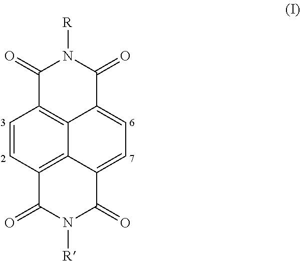

wherein R and R′, equal to or different from each other, are selected from linear or branched alkyl groups, preferably branched, containing from 1 to 36 carbon atoms, preferably from 4 to 24 carbon atoms, more preferably from 6 to 18 carbon atoms, or from aryl groups, preferably phenyl groups, said aryl groups being optionally substituted by alkyl radicals having from 1 to 24 carbon atoms, preferably from 4 to 18 carbon atoms;
at least one electron-donor conjugated structural unit (B), wherein unit (A) is connected to unit (B), in the alternating copolymer, in any of the positions 2, 3, 6 or 7; (d) alternating or statistical conjugated copolymers comprising: at least one benzotriazole unit (B) having general formula (Ia) or (Ib):

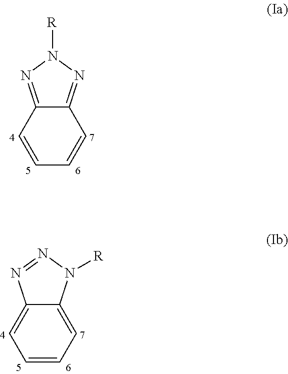

wherein the group R is selected from alkyl groups, aryl groups, acyl groups, thioacyl groups, said alkyl, aryl, acyl and thioacyl groups being optionally substituted;
at least one conjugated structural unit (A), wherein each unit (B) is connected to at least one unit (A) in any of the positions 4, 5, 6 or 7, preferably in positions 4 or 7; (e) alternating π-conjugated polymers comprising:
at least one fluoroarylvinylidene electron-acceptor unit (A) having general formula (III):

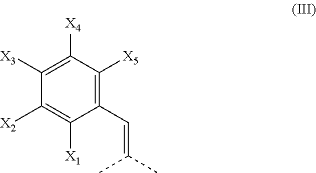

wherein the substituents X₁-X₅, equal to or different from each other, are selected from hydrogen, fluorine, or from alkyl groups containing from 1 to 12 carbon atoms, preferably from 1 to 4 carbon atoms, and on the condition that at least 1, preferably at least 2, more preferably at least 3, of the substituents X₁-X₅ is fluorine, or a —CF₂R group, wherein R is selected from hydrogen, fluorine, or from hydrocarbon groups having from 1 to 10 carbon atoms, said hydrocarbon groups being optionally fluorinated; at least one conjugated electron-donor structural unit (B) connected to the unit (A) in the points indicated by the dashed lines in the general formula (III); (f) copolymers based on acridone units comprising: a monomeric unit (A) having general formula (IV):

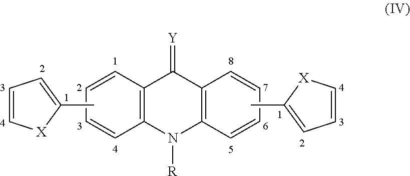

wherein X is selected from sulfur, selenium; Y is selected from oxygen, sulfur, or from —NR′ groups; R and R′, equal to or different from each other, are organic substituents having from 1 to 24 carbon atoms selected from alkyl groups, aryl groups, said alkyl groups being optionally substituted, acyl groups, thioacyl groups; at least one monomeric unit (B) having general formula (V):

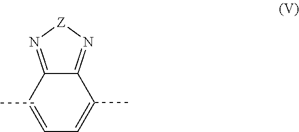

wherein Z is selected from O, S, Se, or from —NR″ groups wherein R″ is an organic substituent having from 1 to 24 carbon atoms selected from alkyl groups, aryl groups, said alkyl and aryl groups being optionally substituted, acyl groups, thioacyl groups; said monomeric unit (B) being connected to any position available of a heteroaromatic side ring of the unit (A) through one of the two positions indicated by the dashed lines in the general formula (V); (g) alternating conjugated copolymers comprising benzothiadiazole units such as, for example, PCDTBT {poly[N-9″-heptadecanyl-2,7-carbazole-alt-5,5-(4′,7′-di-2-thienyl-2′,1′,3′-benzothia-diazole]}, PCPDTBT {poly[2,6-(4,4-bis-(2-ethylhexyl)-4H-cyclopenta-[2,1-b;3,4-b′]-dithio phene)-alt-4,7-(2,1,3-benzothia diazole)]}; (h) alternating conjugated copolymers comprising thieno[3,4-b]pyrazine units; (i) alternating conjugated copolymers comprising quinoxaline units; (l) alternating conjugated copolymers comprising silole monomeric units such as, for example, copolymers of 9,9-dialkyl-9-silafluorene; (m) alternating conjugated copolymers comprising condensed thiophene units such as, for example, copolymers of thieno[3,4-b]thiophene and benzo[1,2-b:4,5-b′]dithiophene; or mixtures thereof.

For the purposes of the present description and of the following claims, the definitions of the numerical ranges always include the extremes unless otherwise specified.

More details relating to alternating conjugated copolymers (c) comprising naphthalenediimide units (A) and at least one electron-donor conjugated structural unit (B) and to the process for their preparation, can be found, for example, in international patent application WO 2010/006698 in the name of the Applicant.

More details relating to alternating or statistical conjugated copolymers (d) comprising at least one benzotriazole unit (B) and at least one conjugated structural unit (A) and to the process for their preparation, can be found, for example, in Italian patent application MI08A001869 in the name of the Applicant.

More details relating to alternating π-conjugated polymers (e) comprising at least one fluoroarylvinylidene electron-acceptor unit (A) and at least one electron-donor conjugated structural unit (B) and to the process for their preparation can be found, for example, in Italian patent application MI09A002150 in the name of the Applicant.

More details relating to copolymers based on acridone units (f) comprising a monomeric unit (A) and at least one monomeric unit (B) and to the process for their preparation, can be found, for example, in Italian patent application MI09A002232 in the name of the Applicant.

More details relating to alternating conjugated copolymers comprising benzothiadiazole units (g), alternating conjugated copolymers comprising thieno[3,4-b]pyrazine units (h), alternating conjugated copolymers comprising quinoxaline units (i), alternating conjugated copolymers comprising silole monomeric units (l), alternating conjugated copolymers comprising condensed thiophene units (m), can be found, for example, in “Accounts of chemical research” (2009), Vol. 42, No. 11, pages 1709-1718, “Development of Novel Conjugated Donor Polymers for High-Efficiency Bulk-Heterojunction Photovoltaic Device” (Chen et al.).

According to a further preferred embodiment of the present invention, said photoactive organic polymer can be selected from poly(3-hexylthiophene); or from polymers having the following general formulae:

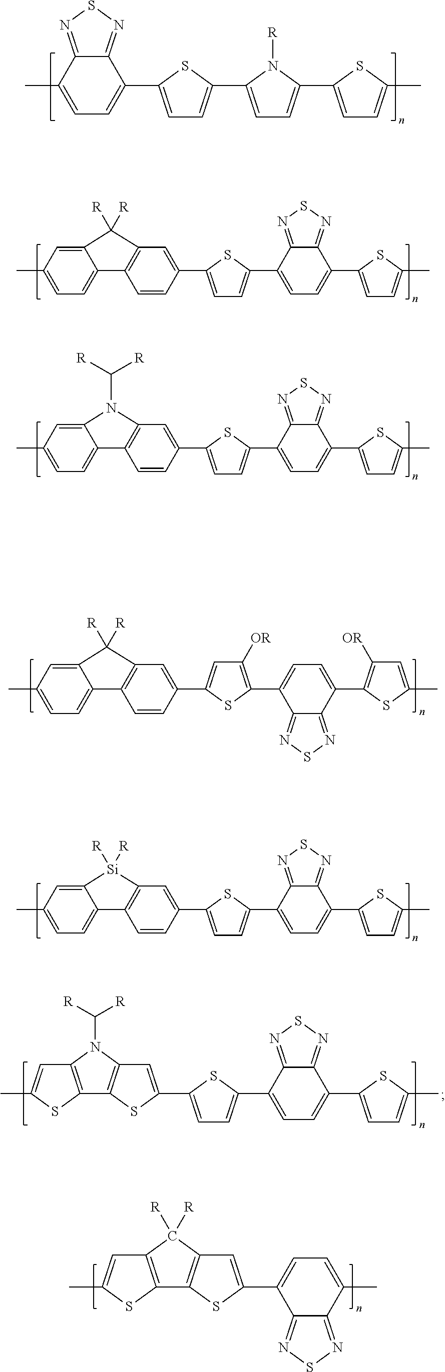

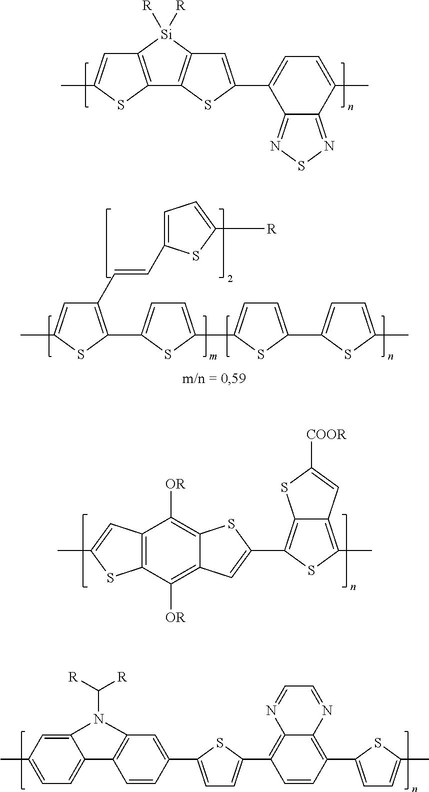

wherein R is a linear or branched C₁-C₂₀, preferably C₆-C₁₅, alkyl group; and n is an integer ranging from 2 to 500, preferably from 5 to 100, extremes included; or mixtures thereof.

Poly(3-hexylthiophene) (P3HT) is preferred.

According to a preferred embodiment of the present invention, said hindered amines can be selected from those having the following general formulae (V)-(XVIII):

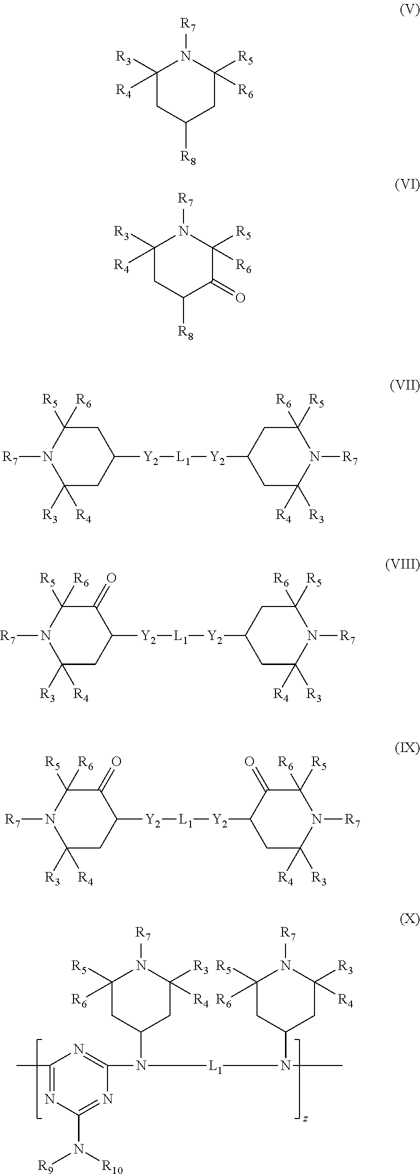

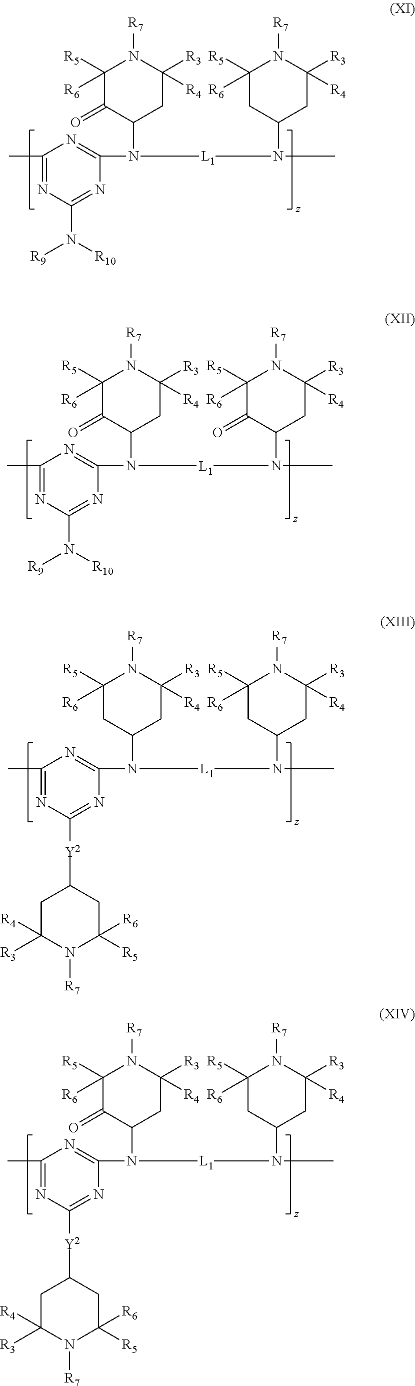

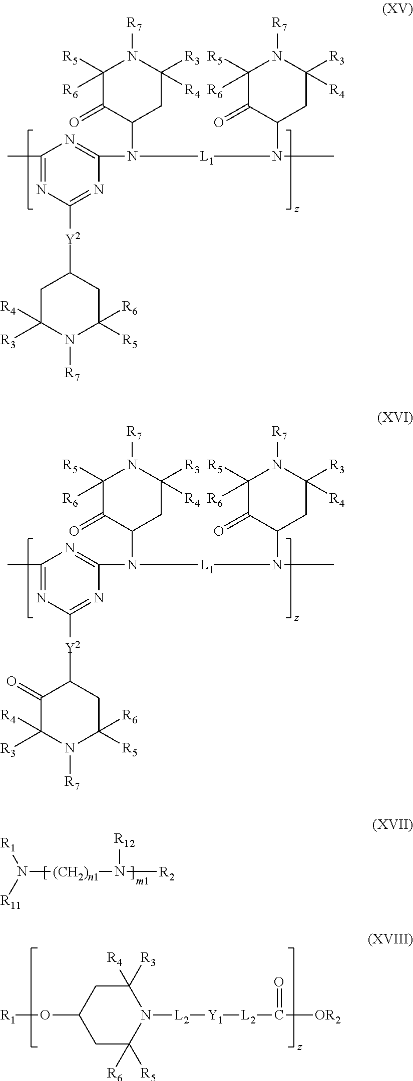

wherein:
R₁ and R₂, equal to or different from each other, are hydrogen, or are selected from C₁-C₂₂ alkyl groups, C₃-C₈ cycloalkyl groups, heteroaryl groups, aryl groups, said alkyl, cycloalkyl, heteroaryl, and aryl groups being optionally substituted;
R₃, R₄, R₅ and R₆, equal to or different from each other, are hydrogen, or are selected from C₁-C₂₂ alkyl groups, C₃-C₈ cycloalkyl groups, heteroaryl groups, aryl groups, said alkyl, cycloalkyl, heteroaryl, and aryl groups being optionally substituted;
R₇ is hydrogen, or is selected from —OR₆ groups wherein R₆ has the meaning described above, C₁-C₂₂ alkyl groups, C₃-C₈ cycloalkyl groups, said alkyl and cycloalkyl groups being optionally substituted;
R₈ is hydrogen, or is selected from C₁-C₂₂ alkyl groups, C₃-C₈ cycloalkyl groups, heteroaryl groups, aryl groups, said alkyl, cycloalkyl, heteroaryl, and aryl groups being optionally substituted; groups —Y₁—R₁ wherein Y₁ has the meaning described below and R₁ has the meaning described above; succinimide groups having general formula (XIX);

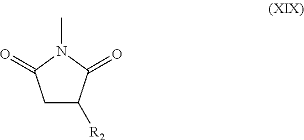

wherein R₂ has the meaning described above;
R₉ and R₁₀, equal to or different from each other, are hydrogen, or are selected from C₁-C₂₂ alkyl groups, C₃-C₈ cycloalkyl groups, said alkyl and cycloalkyl groups being optionally substituted; or R₉ and R₁₀, can jointly represent a divalent group forming a ring with the nitrogen atom to which they are bound, for example, morpholine, piperidine;
L₁ is a divalent connecting group selected from C₂-C₂₂ alkylene groups, —(CH₂CH₂—Y₁)₁₋₃—CH₂CH₂— groups wherein Y₁ has the meaning described below, C₃-C₈ cycloalkylene groups, arylene groups, —CO-L₂-OC— groups wherein L₂ has the meaning described below;
L₂ is selected from C₂-C₂₂ alkylene groups, arylene groups, —(CH₂CH₂—Y₁)₁₋₃—CH₂CH₂— groups wherein Y₁ has the meaning described below, C₃-C₈ cycloalkylene groups;
Y₁ is selected from —OC(O)—, —NHC(O)—, —O—, —S—, —N(R₁)— wherein R₁ has the meaning described above;
Y₂ is selected from —O—, —N(R₁)— wherein R₁ has the meaning described above;
Z is a positive integer lower than or equal to 20, preferably lower than or equal to 6, extremes included;
m1 is a number ranging from 0 to 10, extremes included;
n1 is a positive integer ranging from 2 to 12, extremes included;
R₁₁ and R₁₂, equal to or different from each other, are selected from hydrogen, C₁-C₂₂ alkyl groups, C₃-C₈ cycloalkyl groups, heteroaryl groups, aryl groups, said alkyl, cycloalkyl, heteroaryl, and aryl groups being optionally substituted, radicals (C) having the following general formulae (XX)-(XXII):

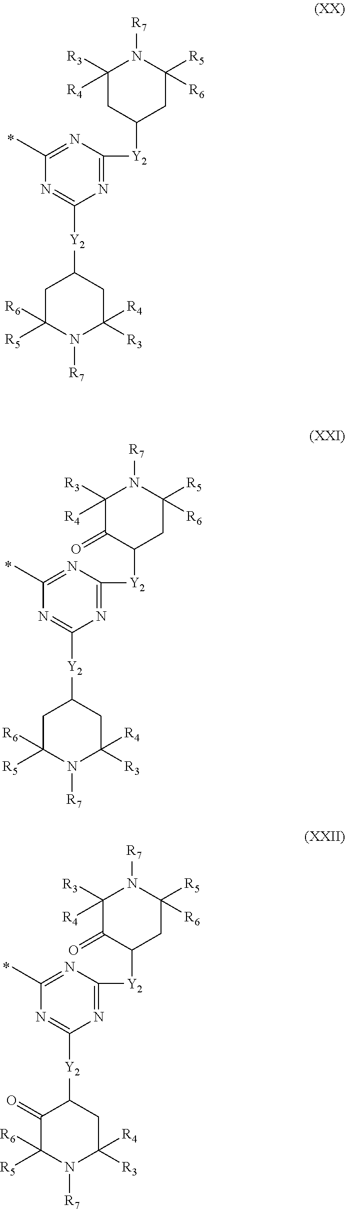

wherein R₃, R₄, R₅, R₆, R₇ and Y₂ have the same meanings described above and the symbol * indicates the attachment position.

The term “C₁-C₂₂ alkyl groups” indicates saturated hydrocarbon radicals containing from 1 to 22 carbon atoms, linear or branched. Specific examples of said C₁-C₂₂ alkyl groups are: methyl, ethyl propyl, butyl, pentyl, hexyl, heptyl, octyl, isopropyl, isobutyl, t-butyl, neopentyl, 2-ethylheptyl, 2-ethylhexyl. Said C₁-C₂₂ alkyl groups can be optionally substituted with one or more substituents selected from: a hydroxyl group, halogen atoms, a cyano group, heteroaryl groups, C₃-C₈ cycloalkyl groups, substituted C₃-C₈ cycloalkyl groups, C₁-C₆ alkoxyl groups, C₂-C₆alkanoyloxyl groups.

The term “C₃-C₈ cycloalkyl groups” indicates cycloaliphatic hydrocarbon radicals containing from 3 to 8 carbon atoms. Specific examples of said C₃-C₈ cycloalkyl groups are: cyclopropyl, cyclobutyl, cyclohexyl. Said C₃-C₈ cycloalkyl groups can be optionally substituted with one or more substituents selected from: C₁-C₆ alkyl groups, C₁-C₆ alkoxyl groups, a hydroxyl group, halogen atoms.

The term “aryl groups” indicates aromatic radicals containing 6, 10 or 14 carbon atoms in the conjugated aromatic ring. Said aryl groups can be optionally substituted with one or more substituents selected from: C₁-C₆ alkyl groups, C₁-C₆ alkoxyl groups; phenyl groups, said phenyl groups being optionally substituted with C₁-C₆ alkyl groups, C₁-C₆ alkoxyl groups, halogen atoms, C₃-C₈ cycloalkyl groups, halogen atoms; a hydroxyl group; a cyano group; a trifluoromethyl group. Specific examples of said aryl groups are phenyl, naphthyl, phenylnaphthyl, anthracenyl.

The term “heteroaryl groups” indicates conjugated cyclic radicals containing at least one heteroatom selected from sulfur, oxygen, nitrogen. Said heteroaryl groups can be optionally substituted with one or more substituents selected from C₁-C₆ alkyl groups, C₁-C₆ alkoxyl groups; phenyl groups; phenyl groups substituted with C₁-C₆ alkyl groups, C₁-C₆ alkoxyl groups, halogen atoms, C₃-C₈ cycloalkyl groups, halogen atoms; a hydroxyl group; a cyano group; a trifluoromethyl group. Specific examples of said heteroaryl groups are: 2- and 3-furyl, 2- and 3-thienyl, 2- and 3-pyrrole, 2-, 3-, and 4-pyridyl, benzothiophen-2-yl, benzothiazol-2-yl, benzoxazol-2-yle, benzimidazol-2-yl, 1,3,4-oxadiazol-2-yl, 1,3,4-thiadiazol-2-yl, 1,2,4-thiadiazol-5-yl, isothiazol-5-yl, imidazol-2-yl, quinolyl.

The term “C₁-C₆ alkoxyl groups” and “C₂-C₆ alkanoyloxyl groups” indicates —O—C₁-C₆— alkyls and —OCOC₁-C₆-alkyls, respectively, wherein the term “C₁-C₆ alkyls” indicates saturated hydrocarbons containing from 1 to 6 carbon atoms, linear or branched, and which can be optionally substituted with one or more substituents selected from: halogen atoms, a methoxy group, an ethoxy group, a phenyl group, a hydroxyl group, an acetyloxy group, a propionyloxy group.

The term “halogen atoms” indicates fluorine, chlorine, bromine, iodine, chlorine and bromine however are preferred.

The term “C₂-C₂₂ alkylene groups” indicates divalent hydrocarbon radicals containing from 2 to 22 carbon atoms, linear or branched, and which can be optionally substituted with one or more substituents selected from a hydroxyl group, halogen atoms, C₁-C₆ alkoxyl groups, C₂-C₆ alkanoylalkoxyl groups, aryl groups.

The term “C₃-C₈ cycloalkylene groups” indicates divalent cycloaliphatic radicals containing from 3 to 8 carbon atoms which can be optionally substituted with one or more C₁-C₆ alkyl groups.

The term “arylene groups” indicates 1,2-, 1,3-, and 1,4-phenylene radicals which can be optionally substituted with C₁-C₆ alkyl groups, C₁-C₆ alkoxyl groups, halogen atoms.

According to a further preferred embodiment of the present invention, said hindered amines can be selected from oligomeric hindered amines having general formulae (V), (VII), (X), (XI), (XII), (XIII), (XIV), (XV), (XVI), (XVII), (XVII), or (XVIII), preferably from those having general formula (X), or mixtures thereof.

According to a further preferred embodiment of the present invention, said hindered amines can be selected from those having general formula (X) wherein R₃, R₄, R₅, R₆ and R₇ are methyl; or R₃, R₄, R₅, R₆ are methyl and R₇ is hydrogen; (R₉)(R₁₀)N— form, together with the nitrogen atom to which they are bound, morpholine; L₁ is a C₂-C₆ alkylene group; and Z ranges from 1 to 6.

Specific examples of hindered amines which can be advantageously used for the purposes of the present invention are: Cyasorb® UV-3529 (Cytec Industries), Cyasorb® UV-3346 (Cytec Industries), Cyasorb® UV-3641 (Cytec Industries), Cyasorb® UV-3581 (Cytec Industries), Cyasorb® UV-3853 (Cytec Industries), Tinuvin® 622 (Ciba Specialty Chemicals), Tinuvin® 770 (Ciba Specialty Chemicals), Tinuvin® 765 (Ciba Specialty Chemicals), Tinuvin® 144 (Ciba Specialty Chemicals), Tinuvin® 123 (Ciba Specialty Chemicals), Chimassorb® 944 (Ciba Specialty Chemicals), Chimassorb® 119 (Ciba Specialty Chemicals), Chimassorb® 2020 (Ciba Specialty Chemicals), Lowilite® 76 (Chemtura Corp.), Lowilite® 62 (Chemtura Corp.), Lowilite 94 (Chemtura Corp.), Uvasil 299LM (Chemtura Corp.), Uvasil 299 HM (Chemtura Corp.), Dastib® 1082 (Vocht), Uvinul® 4049H (BASF Corp.), Uvinul® 4050H (Basf Corp.), Uvinul® 5050H (BASF Corp.), Mark® LA 57 (Asahi Denka Co.), Mark® LA 52 (Asahi Denka Co.), Mark® LA 62 (Asahi Denka Co.), Mark® LA 67 (Asahi Denka Co.), Mark® LA 63 (Asahi Denka Co.), Mark® LA 68 (Asahi Denka Co.), Hostavin® N 20 (Clariant Corp.), Hostavin® N 24 (Clariant Corp.), Hostavin® N 30 (Clariant Corp.), Uvasorb® HA 88 (3V Sigma), Goodrite® UV-3034 (BF Goodrich Chemical Co.), Goodrite® UV-3150 (BF Goodrich Chemical Co.), Goodrite® UV-3159 (BF Goodrich Chemical Co.), Sanduvor® 3050 (Clariant Corp.), Sanduvor® PR-31 (Clariant Corp.), UV Check® AM806 (Ferro Corp.), Sumisorb® TM-061 (Sumitomo Chemical Company), Sumisorb® LS-060 (Sumitomo Chemical Company), Nylostab® S-EED (Clariant Corp.), or mixtures thereof. Cyasorb® UV-3529 (Cytec Industries), Cyasorb® UV-3346 (Cytec Industries), Chimassorb® 944 (Ciba Specialty Chemicals), Chimassorb® 119 (Ciba Specialty Chemicals), Tinuvin® 622 (Ciba Specialty Chemicals), are preferred.

According to a further preferred embodiment of the present invention, said hindered amines are selected from those having a molecular weight higher than or equal to 1,000 such as, for example, Cyasorb® UV-3529 (Cytec Industries), Cyasorb® UV-3346 (Cytec Industries).

According to a preferred embodiment of the present invention, said light stabilizer may be present in the photoactive composition in a quantity ranging from 0.005% by weight to 3% by weight, preferably from 0.05% by weight to 1% by weight, with respect to the weight of said photoactive organic polymer.

According to a preferred embodiment of the present invention, said triazines can be selected from those having general formula (XXIII):

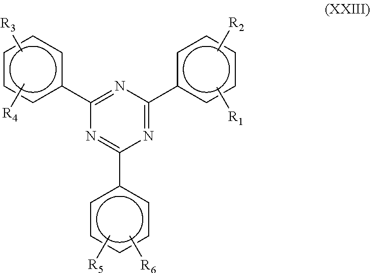

wherein R₁ is hydrogen, or a hydroxyl group; R₂ is hydrogen, or is selected from alkoxyl groups, alkylester groups, hydroxyalkoxyl groups; R₃ is hydrogen, or is selected from alkyl groups; R₄ is hydrogen, or is selected from alkyl groups, alkylester groups; R₅ is hydrogen, or is selected from alkyl groups; R₆ is hydrogen, or is selected from alkylester groups.

According to a preferred embodiment of the present invention, said benzoxazinones can be selected from those having formula (XXIV):

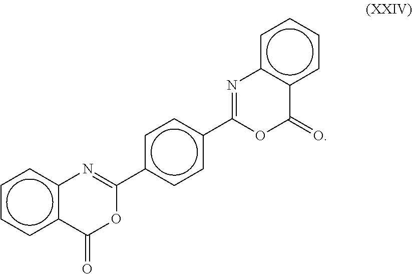

According to a preferred embodiment of the present invention, said benzotriazoles can be selected from those having general formula (XXV):

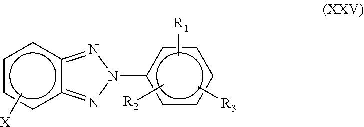

wherein R₁ is hydrogen, or a hydroxyl group; R₂ is selected from alkyl groups, hydroxyalkyl groups, acryloxyalkyl groups, (hydroxyphenyl)alkyl groups, (alkylester)alkyl groups, (hydroxyalkylether)oxoalkyl groups, phenylalkyl groups; X is selected from chlorine, bromine, preferably chlorine.

According to a preferred embodiment of the present invention, said benzophenones can be selected from those having general formula (XXVI):

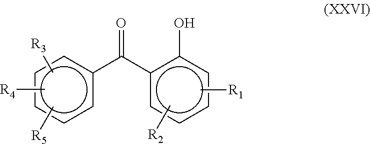

wherein R₁ is a hydroxyl group, or is selected from alkoxyl groups, alkoxyester groups of alkenoic acids, aryloxyl groups, hydroxyalkoxyl groups, hydroxy(alkylether)alkoxyl groups, alkoxyester(acrylo-polymerized) groups, groups deriving from esters of o-alkyl acids; R₂ is hydrogen, a hydroxyl group, a —SO₃H group, or a —SO₃Na group; R₃ is hydrogen, or a hydroxyl group; R₄ is hydrogen, or a hydroxyl group; R₅ is hydrogen, or a —SO₃Na group.

According to a preferred embodiment of the present invention, said benzoates can be selected from those having general formula (XXVII):

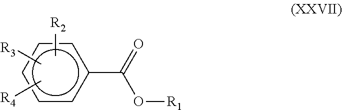

wherein R₁ is selected from hydroxyalkylether groups, alkylphenyl groups, alkyl groups, phenyl groups, hydroxyphenyl groups; R₂ is hydrogen, a hydroxyl group, or it is selected from alkyl groups, hydroxy(alkylether)amine groups; R₃ is hydrogen, a hydroxyl group, or it is selected from alkyl groups; R₄ is hydrogen, or it is selected from alkyl groups.

According to a preferred embodiment of the present invention, said formamidines can be selected from those having general formula (XXVIII):

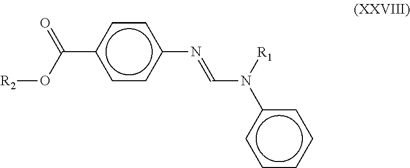

wherein R₁ and R₂, equal to or different from each other, are selected from alkyl groups.

According to a preferred embodiment of the present invention, said cinnamates or propenoates can be selected from those having general formula (XXIX):

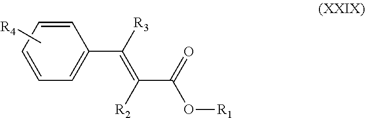

wherein R₁ is selected from alkyl groups; R₂ is a cyano group, or it is selected from alkylester groups; R₃ is hydrogen, or it is selected from phenyl groups; R₄ is hydrogen, or it is selected from alkoxyl groups.

According to a preferred embodiment of the present invention, said aromatic propanediones can be selected from those having general formula (XXX):

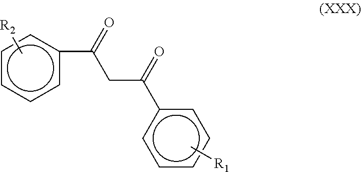

wherein R₁ is selected from alkoxyl groups; R₂ is selected from alkyl groups.

According to a preferred embodiment of the present invention, said benzoimidazoles can be selected from those having general formula (XXXI):

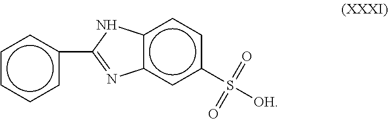

According to a preferred embodiment of the present invention, said cycloaliphatic ketones can be selected from those having general formula (XXXII):

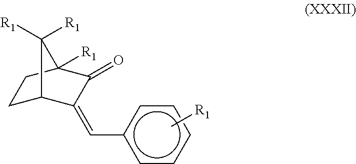

wherein R₁ is selected from alkyl groups.

According to a preferred embodiment of the present invention, said formanilides including oxamides can be selected from those having general formula (XXXIII):

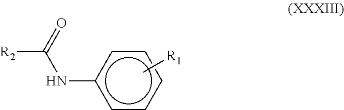

wherein R₁ is selected from alkyl groups; R₂ is hydrogen, a formanilide group, or it is selected from alkylalkoxyl groups, groups containing benzimidazoles.

According to a preferred embodiment of the present invention, said cyanoacrylates can be selected from those having general formula (XXXIV):

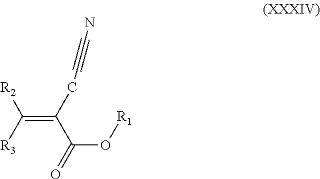

wherein R₁ is selected from alkyl groups, arylcyanoacrylalkyl groups; R₂ is hydrogen, or is selected from phenyl groups, indoline alkyl groups; R₃ is hydrogen, or it is selected from phenyl groups.

According to a preferred embodiment of the present invention, said benzopyranones can be selected from those having general formula (XXXV):

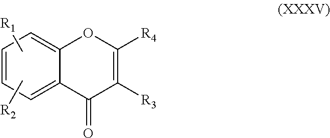

wherein R₁, R₂, R₃ and R₄ are a hydroxyl group.

According to a preferred embodiment of the present invention, said salicylates can be selected from those having general formula (XXXVI):

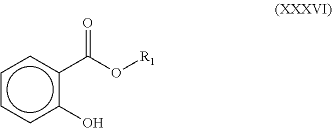

wherein R₁ is selected from linear, branched or cyclic alkyl groups.

According to a further preferred embodiment of the present invention, said UV absorber can be selected from: triazines having general formula (XXIII), benzoates having general formula (XXVII), or mixtures thereof.

According to a further preferred embodiment of the present invention, said UV absorber can be selected from triazines having general formula (XXIII), wherein R₁ is a hydroxyl group; R₂ is an alkoxyl group, preferably an octyloxyl group; R₃ is an alkyl group, preferably a methyl group; R₄ is an alkyl group, preferably a methyl group; R₅ is an alkyl group, preferably a methyl group; R₆ is an alkyl group, preferably a methyl group.

According to a further preferred embodiment of the present invention, said UV absorber can be selected from benzoates having general formula (XXVII), wherein R₁ is an alkyl group, preferably a hexadecyl group; R₂ and R₄ are an alkyl group, preferably a t-butyl group; R₃ is a hydroxyl group.

Specific examples of triazines which can be advantageously used for the purposes of the present invention are: 2-[4,6-bis(2,4-dimethylphenyl)-1,3,5-triazin-2-yl]-5-octyloxyphenol [Cyasorb® UV-1164 (Cytec Industries)], 2-(4,6-diphenyl-1,3,5-triazin-2-yl)-5-hexyloxyphenol [Tinuvin® 1577 FF (Ciba Specialty Chemicals), 2-{4-[(2-hydroxy-3-dodecyloxypropyl)oxy]-2-hydroxyphenyl}-4,6-bis(2,4-dimethylphenyl)-1,3,5-triazine [Tinuvin® 400 (Ciba Specialty Chemicals)], 2,4,6-trianiline-p-(carbo-2′-ethylhexyl-1′-oxy)-1,3,5-triazine [Uvinul® T-150 (Basf Corp.)], or mixtures thereof. 2-[4,6-bis(2,4-dimethylphenyl)-1,3,5-triazin-2-yl]-5-octyloxyphenol [Cyasorb® UV-1164 (Cytec Industries)] is preferred.

A specific example of benzoxazinones which can be advantageously used for the purposes of the present invention is: 2,2′-(p-phenylene)-di-3,1-benzoxazin-4-one [Cyasorb® UV-3638 (Cytec Industries)].

Specific examples of benzotriazoles which can be advantageously used for the purposes of the present invention are: 2-(2′-hydroxy-3′,5′-di-t-amylphenyl]-benzotriazole [Cyasorb® UV-2337 (Cytec Industries)], 2-(2′-hydroxy-5′-octylphenyl]benzotriazole [Cyasorb® UV-5411 (Cytec Industries)], 2-[2-hydroxy-5-(1,1,3,3-tetra-methylbutyl)phenyl]benzotriazole [Tinuvin® 329 (Ciba Specialty Chemicals)], 2-[2′-hydroxy-5′-(2-hydroxy-ethyl)]benzotriazole [Norbloc® 6000 (Jansenn Pharmaceutica], 2-(2′-hydroxy-5′-methacrylyloxyethylphenyl)-2H-benzotriazole [Norbloc® 7966 (Jansenn Pharmaceutica of Titusville], 1,1,1-tris(hydroxyphenyl)ethane benzotriazole (THPE BZT), octyl ester of 5-t-butyl-3-(5-chloro-2H-benzotriazol-2-yl)-4-hydroxybenzenepropanoic acid and octyl ester of 3-(5-chloro-2H-benzotriazol-2-yl)-5-t-butyl-4-hydroxybenzene-propanoic acid [Tinuvin® 109 (Ciba Specialty Chemicals)], a-{3-[3-(2H-benzotriazol-2-yl)-5-t-butyl-4-hydroxyphenyl]-1-oxopropyl}-w-hydroxypoly(oxy-1,2-ethanodiyl) and a-{3-[3-(2H-benzotriazol-2-yl)-5-t-butyl-4-hydroxyphenyl]-1-oxopropyl]-w-{3-[3-(2H-benzotriazol-2-yl)-5-t-butyl-4-hydroxyphenyl]oxopropoxy]-poly-(oxy-1,2-ethanodiyl) [Tinuvin® 1130 (Ciba Specialty Chemicals)], 2-(2-hydroxy-3,5-di-t-butylphenyl)benzotriazole [Tinuvin® 320 (Ciba Specialty Chemicals)], 2-(2-hydroxy-3-t-butyl-5-methylphenyl)-5-chloro-2H-benzotriazole [Tinuvin® 326 (Ciba Specialty Chemicals)], 2-(3′,5′-di-t-butyl-2′-hydroxyphenyl)-5-chlorobenzotriazole [Tinuvin® 327 (Ciba Specialty Chemicals)], 2-(2-hydroxy-3,5-di-t-amylphenyl)benzotriazole [Tinuvin® 328 (Ciba Specialty Chemicals)], 3-(2H-benzotriazol-2-yl)-5-t-butyl-4-hydroxybenzenepropanoic acid [Tinuvin® 384 (Ciba Specialty Chemicals)], 2-(2H-benzotriazol-2-yl)-4-methyl-6-dodecyl-phenol [Tinuvin® 571 (Ciba Specialty Chemicals)], 3-(2H-benzotriazol-2-yl)-5-t-butyl-4-hydroxy-1,6-hexanodiyl ester of benzenepropanoic acid and 3-(2H-benzotriazol-2-yl)-5-t-butyl-4-hydroxy-methyl ester of benzene-propanoic acid [Tinuvin® 840 (Ciba Specialty Chemicals)], 2-[2-hydroxy-3,5-bis-(1,1-dimethylbenzyl)phenyl]-2H-benzotriazole [Tinuvin® 900 (Ciba Specialty Chemicals)], 2-(2H-benzotriazol-2-yl)-6-(1-methyl-1-phenylethyl)-4-(1,1,3,3-tetramethylbutyl)-phenol [Tinuvin® 928 (Ciba Specialty Chemicals)], linear or branched C₇-C₉ alkyl esters of 3-(2H-benzotriazol-2-yl)-5-t-butyl-4-hydroxybenzeneprop-anoic acid [Tinuvin® 99 (Ciba Specialty Chemicals)], 2-(2-hydroxy-5-methylphenyl)benzotriazole [Tinuvin® P (Ciba Specialty Chemicals)], 2-(2′-hydroxy-3′-s-butyl-5′-t-butylphenyl)-benzotriazole [Tinuvin® 350 (Ciba Specialty Chemicals)], 2-(2′-hydroxy-5′-t-butylphenyl)benzotriazole [Tinuvin® PS (Ciba Specialty Chemicals)], bis[2-hydroxy-3-(2H-benzotriazol-2-yl)-5-octylphenyl]methane [Tinuvin® 360 (Ciba Specialty Chemicals)], or mixtures thereof.

Specific examples of benzophenones which can be advantageously used for the purposes of the present invention are: 2-hydroxy-4-n-octyloxybenzophenone [Uvinul® 3008 (Basf Corp.)], 2-hydroxy-4-methoxybenzophenone [Uvinul® 3040 (Basf Corp.)], 2-hydroxy-4-methoxy-5-sulfobenzophenone [Uvinul® MS 40 (Basf Corp.)], homopolymer of 4-(2-acryloyloxyethoxy)-2-hydroxybenzophenone [Cyasorb® UV-2126 (Cytec Industries)], 2,2′-dihydroxy-4-methoxybenzophenone [Cyasorb® UV-24 (Cytec Industries)], 2-hydroxy-4-(2-hydroxy-3-decyloxypropoxy)benzophenone and 2-hydroxy-4-(2-hydroxy-3-octyloxypropoxy)benzophenone [Mark® 1535 (Witco Chemical)], 2,4,4′-trihydroxybenzophenone [Maxgard® 200 (Garrison Industries)], 2-hydroxy-4-(isooctyloxy)benzophenone [Maxgard® 800 (Garrison Industries)], 2-hydroxy-4-dodecyloxybenzophenone [Uvinul® 410 (Basf Corp.)], disodium salt of 2,2′-dihydroxy-4,4′-dimethoxy-5,5′-disulfobenzophenone [Uvinul® 3048 (Basf Corp.)], 2,4-dihydroxybenzophenone [Uvinul® 400 (Basf Corp.)], 2,2′-dihydroxy-4,4′-dimethoxybenzophenone [Uvinul® D 49 (Basf Corp.)], 2,2′,4,4′-tetrahydroxybenzophenone [Uvinul® D 50 (Basf Corp.)], 2,2′-dihydroxy-4-(2-hydroxyethoxy)benzophenone [Uvinul® X-19 (Basf Corp.)], 2-hydroxy-4-benzyloxybenzophenone [Seesorb® 105 (Shipro Kasei Kaisha)], or mixtures thereof.

Specific examples of benzoates which can be advantageously used for the purposes of the present invention are: hexadecyl-3,5-di-t-butyl-4-hydroxybenzoate [Cyasorb® UV-2908 (Cytec Industries)], 3-hydroxyphenylbenzoate [Seesorb® 300 (Shipro Kasei Kaisha)], ethyl-4-{[(ethylphenylamino)methylene]-amino}benzoate [Givsorb® UV-1 (Givauden-Roure Corp.)], phenyl-2-hydroxybenzoate [Seesorb® 201 (Shipro Kasei Kaisha)], 2,4-di-t-butylphenyl-3,5-di-t-butyl-4-hydroxybenzoate [Tinuvin® 120 (Ciba Specialty Chemicals)], polyethoxyethyl ester of 4-bis(polyethoxy)amino acid [Uvinul® P 25 (Basf Corp.)], 4-t-butylphenyl-2-hydroxybenzoate [Seesorb® 202 (Shipro Kasei Kaisha)], or mixtures thereof. Hexadecyl-3,5-di-t-butyl-4-hydroxybenzoate [Cyasorb® UV-2908 (Cytec Industries)] is preferred.

A specific example of formamidines which can be advantageously used for the purposes of the present invention is: ethyl-4-{[(methylphenyl-amino)methylene]amino}-benzoate [Givsorb® UV-2 (Givauden-Roure Corp.)].

Specific examples of cinnamates or propenoates which can be advantageously used for the purposes of the present invention are: dimethyl(p-methoxybenzylidene)-malonate [Sanduvor® PR 25 (Clariant Corp.)], 2-ethylhexyl ester of 3-(4-methoxyphenyl)-2-propenoic acid [Uvinul® 3039 (Basf Corp.)], or mixtures thereof.

A specific example of aromatic propanediones which can be advantageously used for the purposes of the present invention is: 4-t-butyl-4′-methoxydibenzoylmethane [Givsorb® UV-14 (Givauden-Roure Corp.)].

A specific example of benzoimidazoles which can be advantageously used for the purposes of the present invention is: 2-phenyl-1H-benzimidazole-5-sulfonic acid, [Givsorb® UV-16 (Givauden-Roure Corp.)].

A specific example of cycloaliphatic ketones which can be advantageously used for the purposes of the present invention is: 3-(4-methylbenzylidene)-D,L-camphor [Givsorb® UV-15 (Givauden-Roure Corp.)]

Specific examples of formanilides including oxamides which can be advantageously used for the purposes of the present invention are: N-(2-ethoxyphenyl)-N′-(4-isododecylphenyl)oxamide [Sanduvor® 3206 (Clariant Corp.)], N-[5-t-butyl-2-ethoxyphenyl)-N′-(2-ethylphenyl)-oxamide [Tinuvin® 315 (Ciba Specialty Chemicals)], N-(2-ethoxyphenyl)-N′-(2-ethylphenyl)oxamide [Tinuvin® 312 (Ciba Specialty Chemicals)], 2H-benzimidazole-2-carboxylic acid (4-ethoxyphenyl)amide [Uvinul® FK 4105 (Basf Corp.)], or mixtures thereof.

Specific examples of cyanoacrylates which can be advantageously used for the purposes of the present invention are: ethyl-2-cyano-3,3-diphenylacrylate [Uvinul® 3035 (Basf Corp.)], 2-ethylhexyl-2-cyano-3,3-diphenylacrylate [Uvinul® 3039 (Basf Corp.)], 1,3-bis-[(2′-cyano-3,3′-diphenylacryloyl)oxy]-2,2-bis-{[(2-cyano-3′,3′-diphenyl-acryloyl)oxy]methyl}propane [Uvinul® 3030 (Basf Corp.)], 2-cyano-3-(2-methylindolinyl)methylacrylate [UV Absorber Bayer 340], or mixtures thereof.

A specific example of benzopyranones which can be advantageously used for the purposes of the present invention is: 3,3′,4′,5,7-pentahydroxyflavone.

Specific examples of salicylates which can be advantageously used for the purposes of the present invention are: 3,3,5-trimethylcyclohexylsalicylate [Neo Heliopian® HMS (Haarmann & Reimer)], methyl-o-aminobenzoate [Neo Heliopian® MA (Haarmann & Reimer)], or mixtures thereof.

According to a preferred embodiment of the present invention, said UV absorber can be present in the photoactive composition in a quantity ranging from 0.005% by weight to 3% by weight, preferably from 0.05% by weight to 1% by weight, with respect to the weight of said photoactive organic polymer.

According to a preferred embodiment of the present invention, said photoactive composition can comprise at least one antioxidant.

According to a further preferred embodiment of the present invention, said antioxidant can be selected from: 2′,3-bis[3,5-di-t-butyl-4-hydroxyphenyl)propionyl]-propionhydrazide [Irganox® MD 1024 (Ciba Specialty Chemicals)], triethyleneglycol bis-3-(t-butyl-4-hydroxy-5-methylphenyl)propionate [Irganox® 245 (Ciba Specialty Chemicals)], pentaerythritol tetrakis[3-(3,5-di-t-butyl-4-hydrohydroxyphenyl)]propionate [Irganox® 1010 (Ciba Specialty Chemicals)], octadecyl-3,5-di-t-butyl-4-hydroxyhydrocinnamate [Irganox® 1076 (Ciba Specialty Chemicals)], C₇-C₉ branched alkyl esters of 3,5-di-t-4-hydroxyhydrocinnamic acid [Irganox® 1135 (Ciba Specialty Chemicals)], reaction product between N-phenylbenzeneamine and 2,4,4-trimethylpentene [Irganox® 5057 (Ciba Specialty Chemicals)], 1,3,5-tris-(4-t-butyl-3-hydroxy-2,6-dimethylbenzyl)-1,3,5-triazin-2,4,6-(1H, 3H, 5H)trione [Cyanox® 1790 (Cytec Industries)], aryl phosphonite [Sandostab® P-EPQ (Clariant Corp.)], tris-(2,4-di-t-butyl-phenyl)phosphite [Irgafos® 168, (Ciba Specialty Chemicals)]; mixture of 1,3,5-tris-(4-t-butyl-3-hydroxy-2,6-dimethylbenzyl)-1,3,5-triazine-2,4,6-(1H, 3H, 5H)trione:tris-(2,4-di-t-butyl-phenyl)phosphite 1:2 [Cyanox® 2777 (Cytec Industries)]; or mixtures thereof.

Other antioxidants belonging to the group of sterically hindered phenols which can be advantageously used for the purposes of the present invention are: 2,6-di-t-butyl-4-methylphenol, 2,6-di-t-butyl-4-nonyl-phenol, 2,2′-methylene-bis-(4-methyl-6-t-butyl-phenol), 4,4′-butylidene-bis-(2-t-butyl-5-methyl-phenol), 4,4′-thio-bis-(2-t-butyl-5-methylphenol), 2,2′-thio-bis(6-t-butyl-4-methylphenol), 2,5-di-t-amyl-hydroquinone, polymeric sterically hindered phenols, tris-(3,5-di-t-butyl-4-hydroxybenzyl)isocyanurate, 2,2′-thiodiethyl bis-(3,5-di-t-butyl-4-hydroxyphenyl)propionate, 1,1,3-tris-(2′-methyl-4′-hydroxy-5′-t-butyl-phenyl)butane, 2,2′-methylene-bis-6-(1-methylcyclohexyl)-para-cresol, 2,4-dimethyl-6-(1-methylcyclohexyl)-phenol, N,N′-hexamethylene bis-(3,5-di-t-butyl-4-hydroxy-hydro-cinnamamide), or mixtures thereof.

Other antioxidants belonging to the group of phosphites which can be advantageously used for the purposes of the present invention are: tris-(2,4-di-t-butyl-phenyl)phosphite, tris-(2,4-di-t-butyl-phenyl)-phosphite plus distearyl-3,3-thiodipropionate (about 3% by weight with respect to the weight of the phosphite), bis-(2,4-di-t-butyl-phenyl)pentaerythritol-diphosphite, tetrakis-(2,4-di-t-butyl-phenyl)-4,4′-biphenylene-diphosphonite, tris-(p-nonylphenyl)phosphite, diisodecyl-phenyl-phosphite, diphenyl-isodecyl-phosphite, triisodecyl-phosphite, trilauryl-phosphite, or mixtures thereof.

According to a preferred embodiment of the present invention, said antioxidant may be present in the photoactive composition in a quantity ranging from 0.005% by weight to 3% by weight, preferably from 0.05% by weight to 1% by weight, with respect to the weight of said photoactive organic polymer.

Said stabilized photoactive composition can be advantageously used in the construction of photovoltaic devices such as, for example, photovoltaic cells, photovoltaic modules, solar cells, solar modules.

A further object of the present invention therefore relates to the use of said stabilized photoactive composition in the construction of photovoltaic devices such as, for example, photovoltaic cells, photovoltaic modules, solar cells, solar modules.

Furthermore, an additional object of the present invention relates to a photovoltaic device comprising the photoactive composition described above.

Some illustrative and non-limiting examples are provided hereunder for a better understanding of the present invention and for its embodiment.

### Example 1

Two separate solutions were prepared:

solution A: 1.51 g of poly(3-hexylthiophene) (P3HT) (Aldrich, regioregular) were dissolved in 50 ml of 1,2-dichlorobenzene;

solution B: 0.453 g of the commercial mixture Cyasorb® THT 4611 (Cytec Industries) were dissolved in 50 ml of 1,2-dichlorobenzene.

10.0 ml of solution A and 0.1 ml of solution B were then mixed, obtaining a solution in 1,2-dichlorobenzene of poly(3-hexylthiophene) and Cyasorb® THT 4611 [0.3% by weight with respect to the weight of poly(3-hexylthiophene)] (solution C).

A film was prepared from solution C by spin-coating deposition (Spin Coater KW-4A of Chemat Technology) on an inert support of calcium fluoride (CaF₂), operating at 500 rpm, for 60 seconds, in the air, at room temperature (25° C.), using 0.5 ml of solution C.

The film obtained from the above solution C, after evaporation of the solvent, had a thickness equal to 0.6 μm (the thickness was measured with a profilometer Dektak 150 Surface Profiler of Veeco Metrology).

For comparative purposes, operating analogously by spin-coating deposition (Spin Coater KW-4A of Chemat Technology) on an inert support of calcium fluoride (CaF₂), a film was prepared from solution A, operating at 500 rpm, for 60 seconds, in the air, at room temperature (25° C.), using 0.5 ml of solution A.

The film of poly(3-hexylthiophene) (P3HT) obtained from the above solution A, after evaporation of the solvent, had a thickness equal to 0.6 μm (the thickness was measured with a profilometer Dektak 150 Surface Profiler of Veeco Metrology).

The films obtained as described above were simultaneously subjected to accelerated aging in an Atlas Suntest CPS+ with a Xenon lamp, operating at 50° C., with an irradiation equal to 700 W/m².

The degradation of the poly(3-hexylthiophene) (P3HT) was monitored through infrared UV-Vis spectroscopy in transmission mode, removing the films to be analyzed at pre-established time intervals from the Xenotest.

The infrared spectra where collected by means of a Nicolet Nexus 670 FT-IR spectrometer within the range of 4000 cm⁻¹-1000 cm⁻¹, with 64 scans and a resolution equal to 2 cm⁻¹.

The ultraviolet and visible absorption spectra (300 nm-850 nm) were recorded with a double-beam and double monochromator Perkin Elmer λ 950 UV-Vis-NIR spectrophotometer, with a pass-through band of 2.0 nm and step of 1 nm.

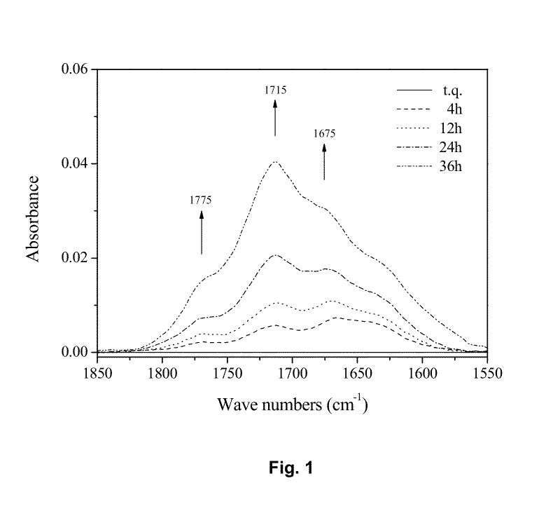

In the films subjected to accelerated aging, the infrared spectroscopy allowed the growth of the carbonyl bands due to the degradation of the poly(3-hexylthiophene) (P3HT), to be monitored. FIG. 1 indicates the evolution observed for the film of poly(3-hexylthiophene) (P3HT), clearly demonstrating the progressive degradation of the material due to exposure to the Xenotest.

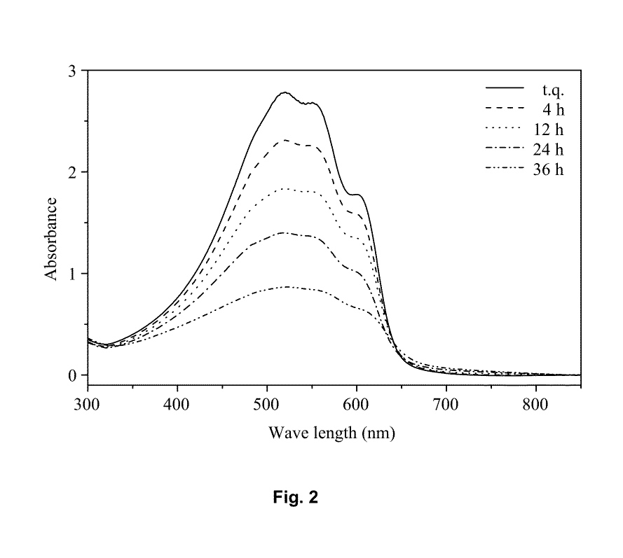

Analogously, UV-Vis absorption spectroscopy allowed the parallel reduction in the absorbance to be monitored in the visible region as shown in FIG. 2, indicating the lesser extent of the conjugation of the system as a result of the polymer backbone degradation.

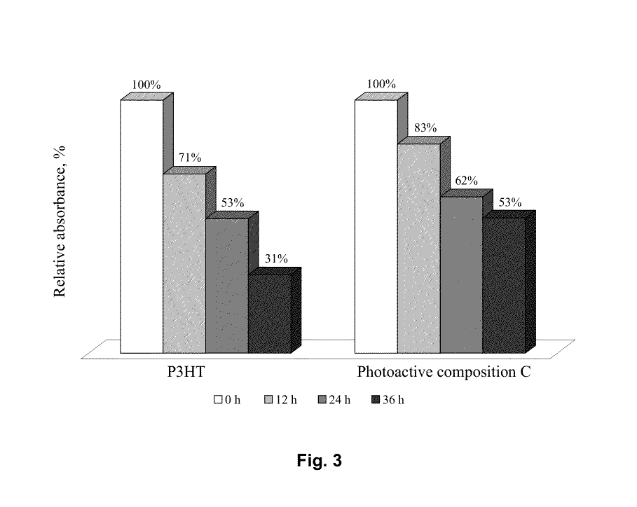

By indicating the relative intensity of the absorption in the visible range of the various films subjected to consecutive irradiation steps with respect to the non-treated films, the trends indicated in FIG. 3 are observed: with the same accelerated aging treatment, the film comprising the photoactive composition, object of the present invention, i.e. the film obtained from the above solution C, shows higher relative absorbances with respect to the film comprising poly(3-hexylthiophene) (P3HT) alone obtained from the above solution A, indicating a lower degradation of the poly(3-hexylthiophene) (P3HT).

### Example 2

Three separate solutions were prepared: solution A1: 0.750 g of poly(3-hexylthiophene) (P3HT) (Aldrich, regioregular) were dissolved in 50 ml of 1,2-dichlorobenzene; solution B1: 0.151 g of the commercial mixture Cyasorb® THT 6435 (Cytec Industries) were dissolved in 50 ml of 1,2-dichlorobenzene; solution C1: 0.152 g of the commercial mixture Cyasorb® THT 4611 (Cytec Industries) were dissolved in 50 ml of 1,2-dichlorobenzene.

10.0 ml of solution A1 and 0.1 ml of solution B1 were then mixed, obtaining a solution in 1,2-dichlorobenzene of poly(3-hexylthiophene) and Cyasorb® THT 6435 [0.2% by weight with respect to the weight of poly(3-hexylthiophene)] (solution D1).

In addition, 10.0 ml of solution A1 and 0.1 ml of solution C1 were mixed, obtaining a solution in 1,2-dichlorobenzene of poly(3-hexylthiophene) and Cyasorb® THT 4611 [0.2% by weight with respect to the weight of poly(3-hexylthiophene)] (solution E1).

A film was prepared from solution D1 by spin-coating deposition (Spin Coater KW-4A of Chemat Technology) on an inert glass support, operating at 500 rpm, for 18 seconds and at 1,000 rpm for a further 60 seconds, in the air, at room temperature (25° C.), using 0.5 ml of solution D1.

The film obtained from the above solution D1, after evaporation of the solvent, had a thickness equal to 80 nm (the thickness was measured with a profilometer Dektak 150 Surface Profiler of Veeco Metrology.

Analogously, a film was prepared from solution E1 by spin-coating deposition (Spin Coater KW-4A of Chemat Technology) on an inert glass carrier, operating at 500 rpm, for 18 seconds and at 1,000 rpm for a further 60 seconds, in the air, at room temperature (25° C.), using 0.5 ml of solution E1.

The film obtained from the above solution E1, after evaporation of the solvent, had a thickness equal to 80 nm (the thickness was measured with a profilometer Dektak 150 Surface Profiler of Veeco Metrology).

For comparative purposes, operating analogously by spin-coating deposition (Spin Coater KW-4A of Chemat Technology) on an inert glass support, a film was prepared from solution A1, operating at 500 rpm, for 18 seconds and at 1,000 rpm for a further 60 seconds, in the air, at room temperature (25° C.), using 0.5 ml of solution A1.

The film of poly(3-hexylthiophene) (P3HT) obtained from the above solution A1, after evaporation of the solvent, had a thickness equal to 80 nm (the thickness was measured with a profilometer Dektak 150 Surface Profiler of Veeco Metrology).

The films obtained as described above were simultaneously subjected to accelerated aging in an Atlas Suntest CPS+ with a Xenon lamp, operating at 50° C., with an irradiation equal to 700 W/m².

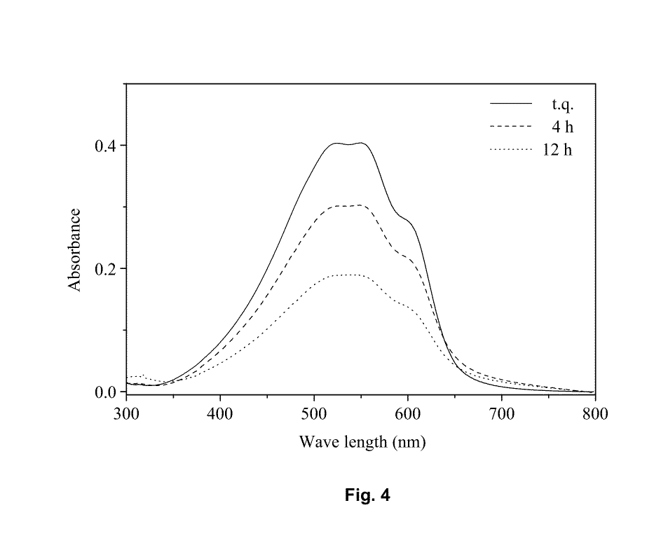

The degradation of the film obtained from the above solution E1 was monitored through ultraviolet and visible absorption spectrophotometry, following the absorbance decrease in the region ranging from 300 nm to 850 nm as indicated in FIG. 4. In this respect, the film to be analyzed was removed from the Xenotest at pre-established time intervals and the absorption spectra were collected with a double-beam and a double monochromator Perkin Elmer λ 950 UV-Vis-NIR spectrophotometer with a pass-through band of 2.0 nm and step of 1 nm.

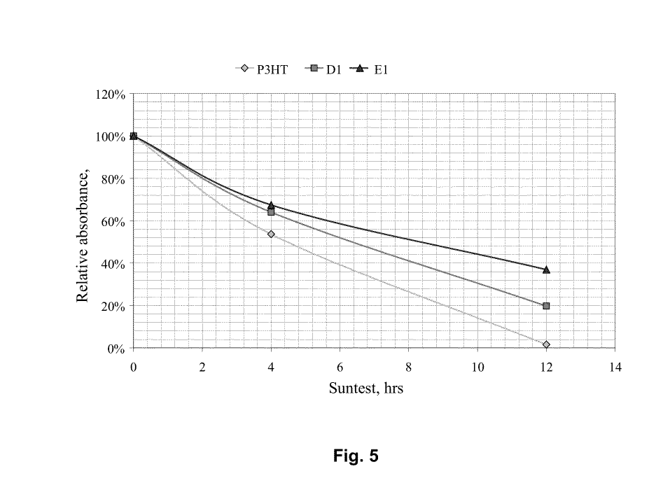

FIG. 5, on the other hand shows the relative absorbance of the film comprising poly(3-hexylthiophene) (P3HT) alone, and also the films comprising the photoactive compositions, object of the present invention, i.e. the films obtained from solution D1 and from solution E1. The results show that, in these particularly thin films, after 12 hours, the film of poly(3-hexylthiophene) (P3HT) obtained from the above solution A1 is almost completely degraded (P3HT), whereas the films comprising the photoactive compositions, object of the present invention, i.e., the films obtained from the above solution D1 and from the above solution E1, still have relative absorbances equal to about 20% (film obtained from the above solution D1) and about 40% (film obtained from the above solution E1), with respect to the initial absorbance of the respective non-aged films.

Having described the invention, the following is claimed:

1. A stabilized photoactive composition comprising:
at least one photoactive organic polymer;
at least one light stabilizer selected from hindered amines;
at least one UV absorber selected from triazines, benzoxazinones, benzotriazoles, benzophenones, benzoates, formamidines, cinnamates or propenoates, aromatic propanediones, benzoimidazoles, cycloaliphatic ketones, formanilides including oxamides, cyanoacrylates, benzopyranones, salicylates, or mixtures thereof.

2. The stabilized photoactive composition according to claim 1, wherein said photoactive organic polymer is selected from:
(a) polythiophenes;
(b) polyphenylenevinylenes;
(c) alternating conjugated copolymers comprising:
naphthalenediimide units (A) having general formula (I): 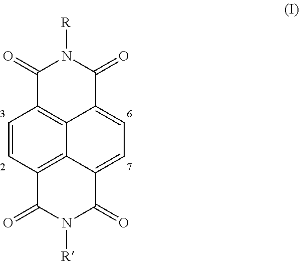
wherein R and R′, equal to or different from each other, are selected from linear or branched alkyl groups, containing from 1 to 36 carbon atoms, or from aryl groups, said aryl groups being optionally substituted by alkyl radicals having from 1 to 24 carbon atoms;
at least one electron-donor conjugated structural unit (B), wherein unit (A) is connected to unit (B), in the alternating copolymer, in any of the positions 2, 3, 6 or 7;
(d) alternating or statistical conjugated copolymers comprising:
at least one benzotriazole unit (B) having general formula (Ia) or (Ib): 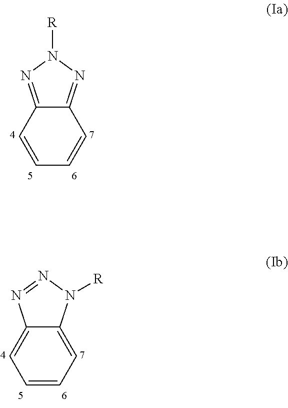
wherein the group R is selected from alkyl groups, aryl groups, acyl groups, thioacyl groups, said alkyl, aryl, acyl and thioacyl groups being optionally substituted;
at least one conjugated structural unit (A), wherein each unit (B) is connected to at least one unit (A) in any of the positions 4, 5, 6 or 7;
(e) alternating π-conjugated polymers comprising:
at least one fluoroarylvinylidene electron-acceptor unit (A) having general formula (III): 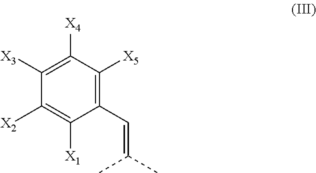
wherein the substituents X₁-X₅, equal to or different from each other, are selected from hydrogen, fluorine, or from alkyl groups containing from 1 to 12 carbon atoms, and on the condition that at least one of the substituents X₁-X₅ is fluorine, or a —CF₂R group, wherein R is selected from hydrogen, fluorine, or from hydrocarbon groups having from 1 to 10 carbon atoms, said hydrocarbon groups being optionally fluorinated;
at least one conjugated electron-donor structural unit (B) connected to the unit (A) in the points indicated by the dashed lines in the general formula (III);
(f) copolymers based on acridone units comprising:
a monomeric unit (A) having general formula (IV): 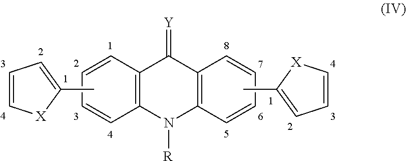
wherein X is selected from sulfur, selenium; Y is selected from oxygen, sulfur, or from —NR′ groups; R ed R′, equal to or different from each other, are organic substituents having from 1 to 24 carbon atoms selected from alkyl groups, aryl groups, said alkyl groups being optionally substituted, acyl groups, thioacyl groups;
at least one monomeric unit (B) having general formula (V): 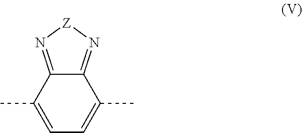
wherein Z is selected from O, S, Se, or from —NR″ groups wherein R″ is an organic substituent having from 1 to 24 carbon atoms selected from alkyl groups, aryl groups, said alkyl and aryl groups being optionally substituted, acyl groups, thioacyl groups; said monomeric unit (B) being connected to any position available of a heteroaromatic side ring of the unit (A) through one of the two positions indicated by the dashed lines in the general formula (V);
(g) alternating conjugated copolymers comprising benzothiadiazole units;
(h) alternating conjugated copolymers comprising thieno[3,4-b]pyrazine units;
(i) alternating conjugated copolymers comprising quinoxaline units;
(l) alternating conjugated copolymers comprising silole monomeric units; and
(m) alternating conjugated copolymers comprising condensed thiophene units.

3. The stabilized photoactive composition according to claim 1, wherein said photoactive organic polymer is selected from poly(3-hexylthiophene); or from polymers having the following general formula: 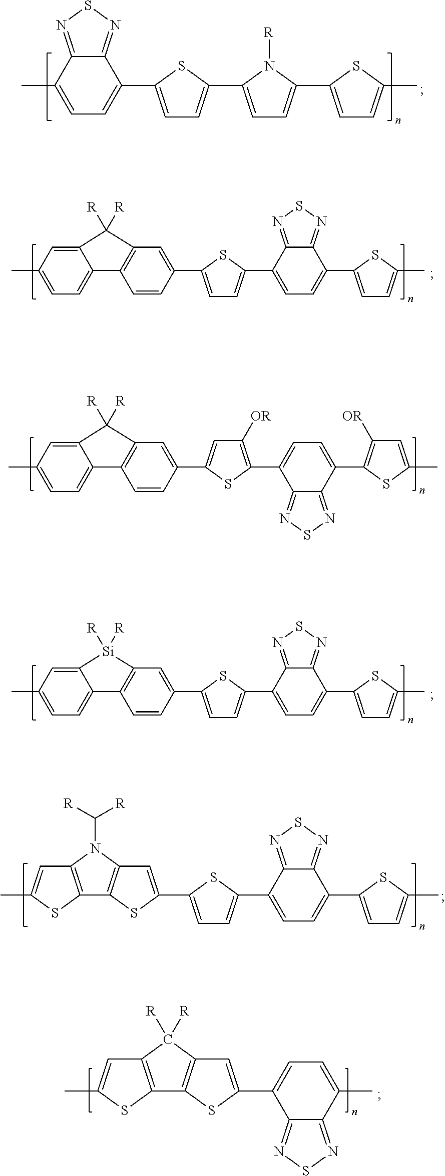 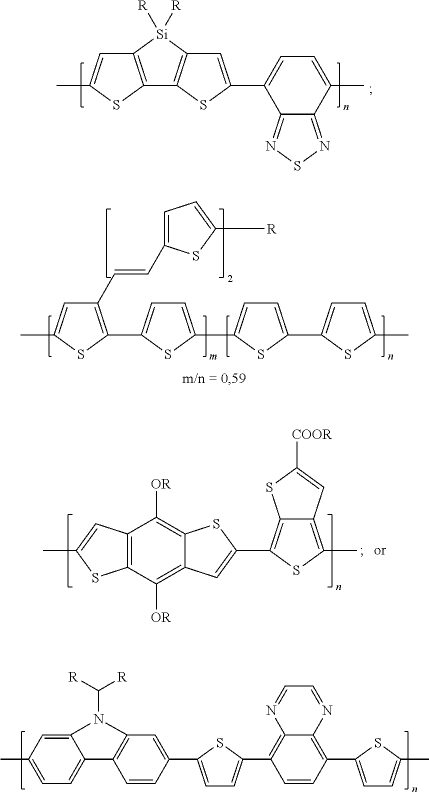
wherein R is a linear or branched C₁-C₂₀ alkyl group; and n is an integer ranging from 2 to 500, extremes included; or mixtures thereof.

4. The stabilized photoactive composition according to claim 1, wherein said hindered amines are selected from those having the following general formulae (V)-(XVIII): 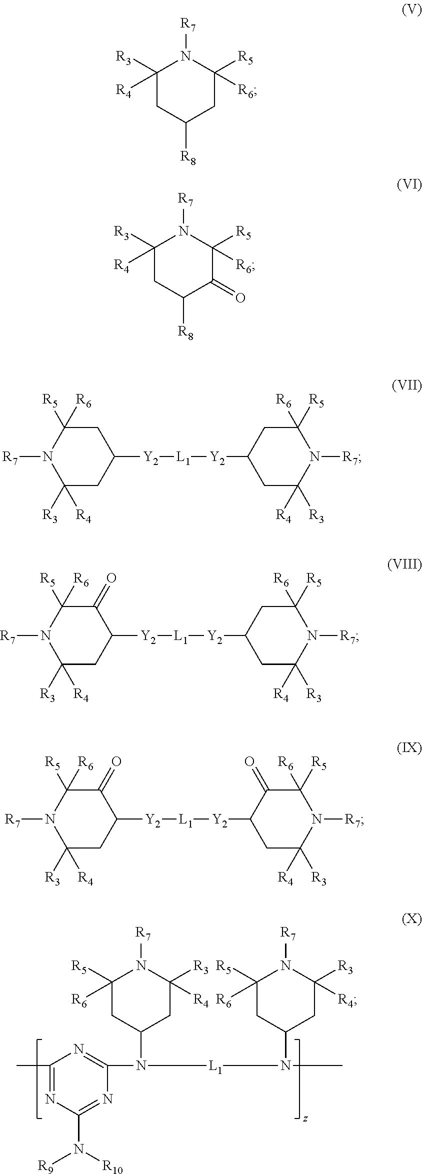 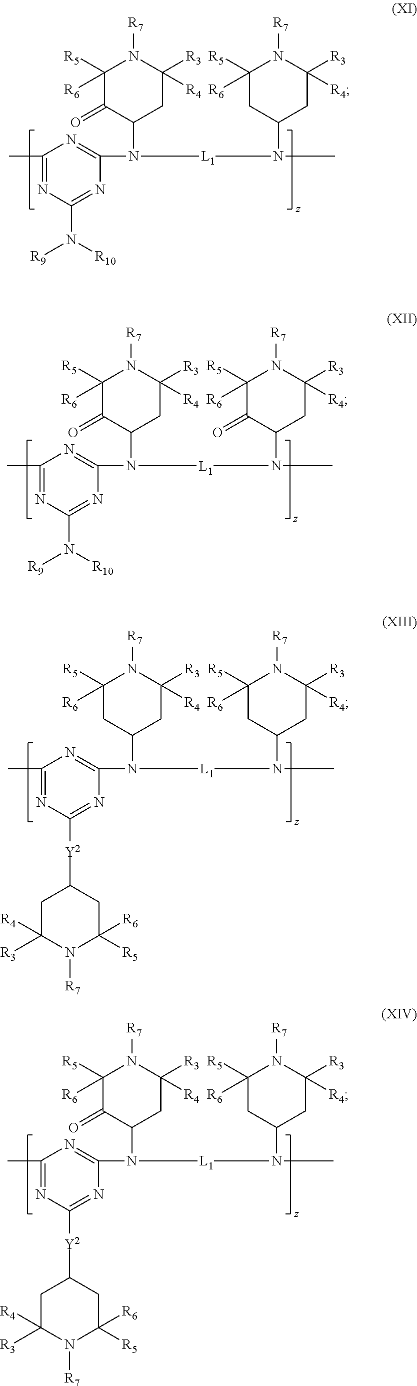 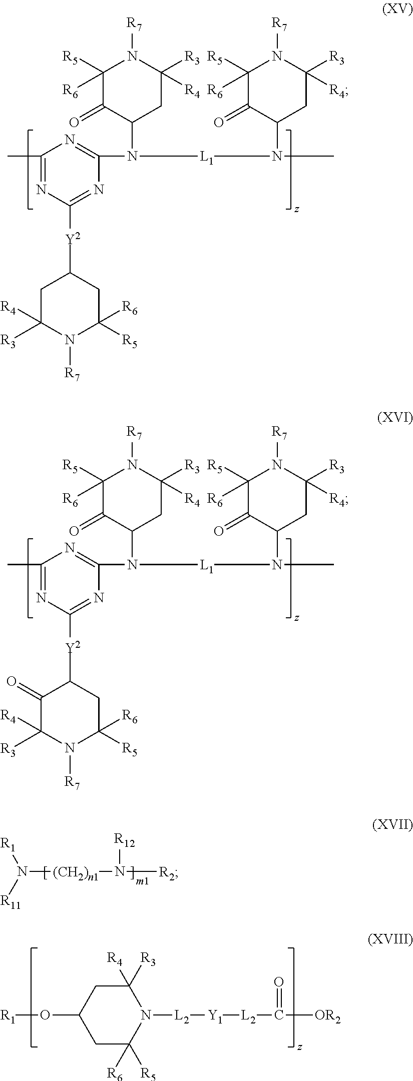
wherein:
R₁ and R₂, equal to or different from each other, are hydrogen, or they are selected from C₁-C₂₂ alkyl groups, C₃-C₈ cycloalkyl groups, heteroaryl groups, aryl groups, said alkyl, cycloalkyl, heteroaryl, and aryl groups being optionally substituted;
R₃, R₄, R₅ and R₆, equal to or different from each other, are hydrogen, or they are selected from C₁-C₂₂ alkyl groups, C₃-C₈ cycloalkyl groups, heteroaryl groups, aryl groups, said alkyl, cycloalkyl, heteroaryl, and aryl groups being optionally substituted;
R₇ is hydrogen, or it is selected from —OR₆ groups wherein R₆ has the meaning described above, C₁-C₂₂ alkyl groups, C₃-C₈ cycloalkyl groups, said alkyl and cycloalkyl groups being optionally substituted;
R₈ is hydrogen, or it is selected from C₁-C₂₂ alkyl groups, C₃-C₈ cycloalkyl groups, heteroaryl groups, aryl groups, said alkyl, cycloalkyl, heteroaryl, and aryl groups being optionally substituted; groups —Y₁—R₁ wherein Y₁ has the meaning described below and R₁ has the meaning described above; succinimide groups having general formula (XIX); 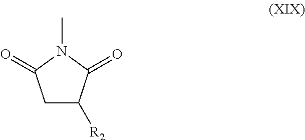
wherein R₂ has the meaning described above;
R₉ and R₁₀, equal to or different from each other, are hydrogen, or they are selected from C₁-C₂₂ alkyl groups, C₃-C₈ cycloalkyl groups, said alkyl and cycloalkyl groups being optionally substituted; or R₉ and R₁₀, can jointly represent a divalent group forming a ring with the nitrogen atom to which they are bound, for example, morpholine, piperidine;
L₁ is a divalent connecting group selected from C₂-C₂₂ alkylene groups, —(CH₂CH₂—Y₁)₁₋₃—CH₂CH₂— groups wherein Y₁ has the meaning described below, C₃-C₈ cycloalkylene groups, arylene groups, —CO-L₂-OC— groups wherein L₂ has the meaning described below;
L₂ is selected from C₂-C₂₂ alkylene groups, arylene groups, —(CH₂CH₂—Y₁)₁₋₃—CH₂CH₂— groups wherein Y₁ has the meaning described below, C₃-C₈ cycloalkylene groups;
Y₁ is selected from —OC(O)—, —NHC(O)—, —O—, —S—, N(R₁)— wherein R₁ has the meaning described above;
Y₂ is selected from —O—, —N(R₁)— wherein R₁ has the meaning described above;
Z is a positive integer lower than or equal to 20;
m1 is a number ranging from 0 to 10, extremes included;
n1 is a positive integer ranging from 2 to 12, extremes included;
R₁₁ and R₁₂, equal to or different from each other, are selected from hydrogen, C₁-C₂₂ alkyl groups, C₃-C₈ cycloalkyl groups, heteroaryl groups, aryl groups, said alkyl, cycloalkyl, heteroaryl, and aryl groups being optionally substituted, radicals (C) having the following general formulae (XX)-(XXII): 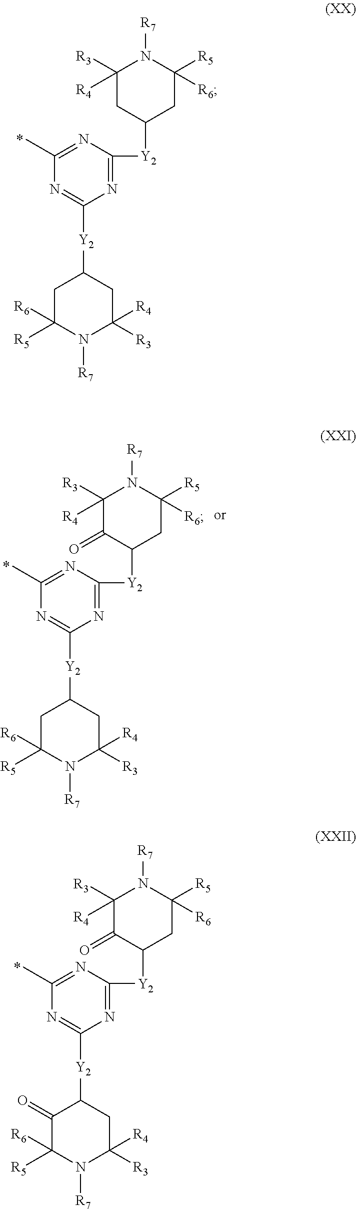
wherein R₃, R₄, R₅, R₆, R₇ and Y₂ have the same meanings described above and the symbol * indicates the attachment position.

5. The stabilized photoactive composition according to claim 4, wherein said hindered amines are selected from those having general formula (X) wherein R₃, R₄, R₅, R₆ and R₇ are methyl; or R₃, R₄, R₅, and R₆ are methyl and R₇ is hydrogen; (R₉)(R₁₀)N— form, together with the nitrogen atom to which they are bound, morpholine; L₁ is a C₂-C₆ alkylene group; and Z ranges from 1 to 6.

6. The stabilized photoactive composition according to claim 1, wherein said triazines are selected from those having general formula (XXIII): 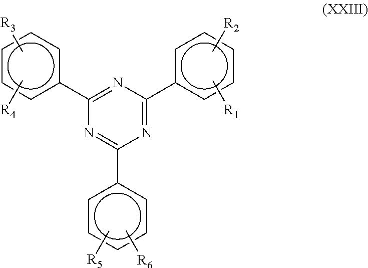
wherein R₁ is hydrogen, or a hydroxyl group; R₂ is hydrogen, or it is selected from alkoxyl groups, alkylester groups, hydroxyalkoxyl groups; R₃ is hydrogen, or it is selected from alkyl groups; R₄ is hydrogen, or it is selected from alkyl groups, alkylester groups; R₅ is hydrogen, or it is selected from alkyl groups; R₆ is hydrogen, or it is selected from alkylester groups.

7. The stabilized photoactive composition according to claim 1, wherein said benzoxazinones are selected from those having formula (XXIV):

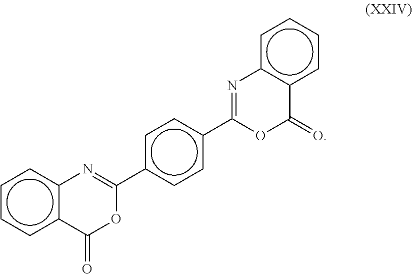

8. The stabilized photoactive composition according to claim 1, wherein said benzotriazoles are selected from those having general formula (XXV): 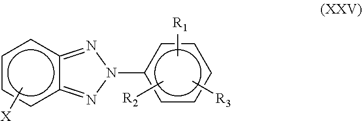
wherein R₁ is hydrogen, or a hydroxyl group; R₂ is selected from alkyl groups, hydroxyalkyl groups, acryloxyalkyl groups, (hydroxyphenyl)alkyl groups, (alkylester)alkyl groups, (hydroxyalkylether)-oxoalkyl groups, phenylalkyl groups; X is selected from chlorine, bromine.

9. The stabilized photoactive composition according to claim 1, wherein said benzophenones are selected from those having general formula (XXVI): 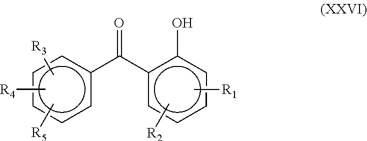
wherein R₁ is a hydroxyl group, or it is selected from alkoxyl groups, alkoxyester groups of alkenoic acids, aryloxyl groups, hydroxyalkoxyl groups, hydroxy(alkylether)alkoxyl groups, alkoxyester-(acrylo-polymerized) groups, groups deriving from esters of o-alkyl acids; R₂ is hydrogen, a hydroxyl group, a —SO₃H group, or a —SO₃Na group; R₃ is hydrogen, or a hydroxyl group; R₄ is hydrogen, or a hydroxyl group; R₅ is hydrogen, or a —SO₃Na group.

10. The stabilized photoactive composition according to claim 1, wherein said benzoates are selected from those having general formula (XXVII): 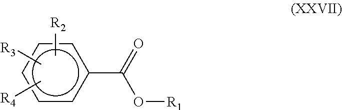
wherein R₁ is selected from hydroxyalkylether groups, alkylphenyl groups, alkyl groups, phenyl groups, hydroxyphenyl groups; R₂ is hydrogen, a hydroxyl group, or it is selected from alkyl groups, hydroxy(alkylether)amine groups; R₃ is hydrogen, a hydroxyl group, or it is selected from alkyl groups; R₄ is hydrogen, or it is selected from alkyl groups.

11. The stabilized photoactive composition according to claim 1, wherein said formamidines are selected from those having general formula (XXVIII): 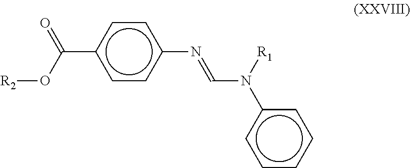
wherein R₁ and R₂, equal to or different from each other, are selected from alkyl groups.

12. The stabilized photoactive composition according to claim 1, wherein said cinnamates or propenoates are selected from those having general formula (XXIX): 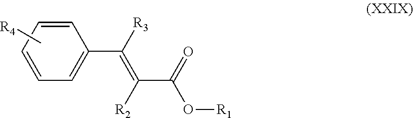
wherein R₁ is selected from alkyl groups; R₂ is a cyano group, or it is selected from alkylester groups; R₃ is hydrogen, or it is selected from phenyl groups; R₄ is hydrogen, or it is selected from alkoxyl groups.

13. The stabilized photoactive composition according to claim 1, wherein said aromatic propanediones are selected from those having general formula (XXX): 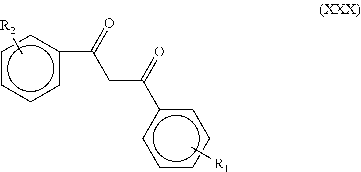
wherein R₁ is selected from alkoxyl groups; R₂ is selected from alkyl groups.

14. The stabilized photoactive composition according to claim 1, wherein said benzoimidazoles are selected from those having general formula (XXXI):

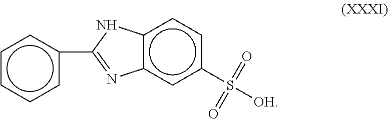

15. The stabilized photoactive composition according to claim 1, wherein said cycloaliphatic ketones are selected from those having general formula (XXXII): 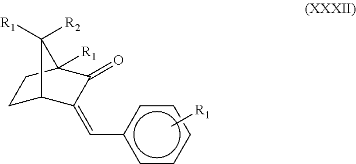
wherein R₁ is selected from alkyl groups.

16. The stabilized photoactive composition according to claim 1, wherein said formanilides including oxamides are selected from those having general formula (XXXIII): 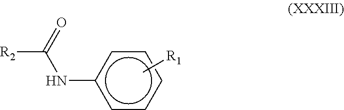
wherein R₁ is selected from alkyl groups; R₂ is hydrogen, a formanilide group, or it is selected from alkylalkoxyl groups, groups containing benzimidazoles.

17. The stabilized photoactive composition according to claim 1, wherein said cyanoacrylates are selected from those having general formula (XXXIV): 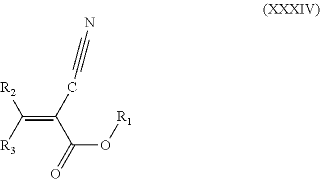
wherein R₁ is selected from alkyl groups, arylcyanoacrylalkyl groups; R₂ is hydrogen, or it is selected from phenyl groups, indoline alkyl groups; R₃ is hydrogen, or it is selected from phenyl groups.

18. The stabilized photoactive composition according to claim 1, wherein said benzopyranones are selected from those having general formula (XXXV): 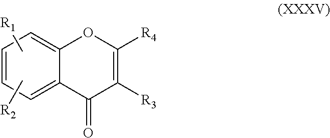
wherein R₁, R₂, R₃ and R₄ are a hydroxyl group.

19. The stabilized photoactive composition according to claim 1, wherein said salicylates are selected from those having general formula (XXXVI): 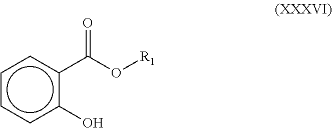
wherein R₁ is selected from linear, branched or cyclic alkyl groups.

20. The stabilized photoactive composition according to claim 1, wherein said UV absorber is selected from triazines having general formula (XXIII), wherein R₁ is a hydroxyl group; R₂ is an alkoxyl group; R₃ is an alkyl group; R₄ is an alkyl group; R₅ is an alkyl group; R₆ is an alkyl group.

21. The stabilized photoactive composition according to claim 1, wherein said UV absorber is selected from benzoates having general formula (XXVII), wherein R₁ is an alkyl group; R₂ and R₄ are an alkyl group; R₃ is a hydroxyl group.

22. The stabilized photoactive composition according to claim 1, wherein said photoactive composition comprises at least one antioxidant.

23. Use of the stabilized photoactive composition according to claim 1, in the construction of photovoltaic devices.

24. A photovoltaic device comprising the photoactive composition according to claim 1.
